(19) United States
(12) Patent Application Publication
(10) Pub. No.: US 2006/0192595 A1
(43) Pub. Date: Aug. 31, 2006

(54) Sense amplifier

(76) Inventors: Rainer Florian Schnabel, Hohenkirchen (DE); Michael Bernhard Sommer, Raubling (DE)

Correspondence Address: EDELL, SHAPIRO & FINNAN, LLC, 1901 RESEARCH BLVD., SUITE 400, ROCKVILLE, MD, 20850, US

(21) Appl. No.: 11/360,996

(22) Filed: Feb. 24, 2006

(30) Foreign Application Priority Data
Feb. 24, 2005 (DE) 10 2005 008516.4

(51) Int. Cl. G01R 19/00

(52) U.S. Cl. 327/51

(57) ABSTRACT

A sense amplifier includes at least two field effect transistors of identical conductivity type, each including a gate terminal, a source terminal, a drain terminal and a bulk terminal. The two field effect transistors are connected such that they are coupled back-to-back between a bit line and a reference line. The bit line is connected to a memory node via a selection transistor. The field effect transistors include bulk or substrate terminals formed in mutually insulated, different wells. The substrate bias voltages and thus the threshold voltages can be set independently via the body effect, so that the threshold voltages that are fundamentally different on account of stochastic effects in the different wells can be adapted to one another. Thus, compensating for the disadvantages that occur in conventional wells, on account of scattering effects during implantation or on account of mechanical stresses which act differently on transistors that are otherwise formed uniformly in the same well.

### CROSS REFERENCE TO RELATED APPLICATIONS

This application claims priority under 35 USC §119 to German Application No. DE 102005008516.4, filed on Feb. 24, 2005, and titled “Sense Amplifier,” the entire contents of which are hereby incorporated by reference.

### FIELD OF THE INVENTION

The invention relates to a sense amplifier. The invention relates, in particular, to those sense amplifiers which have at least one pair of negative-feedback field effect transistors having identical conductivity type within the pair. The sense amplifier preferably serves for amplifying an electrical signal that is read out from a memory cell of a dynamic memory component.

### BACKGROUND

Sense amplifiers serve for amplifying a weak electrical signal present at an input of the sense amplifier. They are also used in particular in the area of memory components, where they are used to amplify the charges that are stored and read out from dynamic random access memory cells (DRAM) as a signal. The strength of the signals of charges stored in trench capacitors, for example, is comparatively weak on account of the smallest possible dimensioning of the trenches.

In the area of nonvolatile memories, e.g., those having memory cells based on the magnetoresistive effect (MRAM) or on floating gate storage (charge trapping devices), weak cell signals usually have to be amplified.

There are various architectures for sense amplifiers. They typically have a respective pair of n-channel and p-channel field effect transistors which may be arranged, e.g., in cross-coupled fashion or in a manner coupled with negative feedback in pairs. In the case of memory components, these are usually arranged at the edges of the memory cell arrays on or in the substrate.

In this case, the threshold voltages of the n-channel and p-channel field effect transistors are of great importance for the amplification:

For example, a gate terminal of a first n-channel field effect transistor of the pair may be connected to the line carrying the signal (signal line hereinafter) and a gate terminal of a second one of the n-channel field effect transistors may be connected to a reference line. The reference line is biased to a comparison potential with which the signal is to be compared for the purpose of the direction of the amplification proceeding from the comparison potential.

In the case of the memories, the signal line corresponds to a bit line and the reference line corresponds to a reference bit line.

By contrast, the source terminals of the two n-channel field effect transistors are connected to the same means for feeding in a supply voltage. The means for feeding in the supply voltage may itself also in turn have a transistor with which the supply voltage is trimmed. In the case of the n-channel field effect transistors, e.g., a potential is run through from a maximum value to a minimum value. The gate-source voltages at the two n-channel field effect transistors (n-FETs hereinafter) then depend on the potentials present on the signal and reference lines in comparison with the trimmed supply potential.

What then matters is which of the continuously decreasing gate-source voltages at the two n-FETs falls below the threshold voltage of the transistors first. If, e.g., the potential on the signal line is higher, then that n-FET whose gate terminal is connected to the signal line turns on first.

The negative-feedback mode of switching connection of the two n-FETs consists in the fact that the drain terminals are in each case connected to that line which is precisely not connected to the gate terminal of the relevant n-FET. This means, however, that the gate terminal of the respectively precisely non-switching n-FET is connected to the decreasing potential, that is to say that until the minimum potential value is reached its conductivity decreases since its gate-source voltage vanishes.

Overall, one of the two lines is thereby run down to a minimum potential. The complementary task—of running the potential of the other line up to the maximum value—is performed analogously by the other pair of p-channel field effect transistors (p-FETs hereinafter).

It is important for the threshold voltages of the two n-FETs or p-FETs to be as far as possible equal among one another, if not in fact identical. In the case of the memories, a typical potential difference between bit line and reference bit line may be 60 millivolts (mV) given threshold voltages of 300-400 mV. If the threshold voltages differ to a sufficiently great extent, however, an amplifier operation in which the signal is amplified in the wrong direction may occur. In this case, the information actually stored in the cell could be interpreted incorrectly during read-out and amplification.

For an n- or p-FET, the threshold voltage is influenced by the purity and quality of the fabrication process. The quality of the formation of the n-type well (in the case of the p-FET) or the p-type well (in the case of the n-FET) is particularly important in this case. The two n-FETs or p-FETs of the sense amplifier are formed in principle on the substrate, in the region of the same n-type or p-type well in each case. The two n- or p-FETs depicted identically in terms of their geometry then generally exhibit a stochastic switching behavior that deviates from one another albeit only to a small extent (so-called “mismatch”). Electrical measurements of a multiplicity of such transistors in this case have a Gaussian distribution in the physical quantities respectively measured, e.g., the threshold voltage.

However, systematic, no longer acceptable differences between two respective transistors of the same conductivity type may occur as well. The term used in this context is a systematic “offset” or “mismatch”. It has thus been established, for example, that the distance between the transistor and the outer edge of the n-type or p-type well influences the measured distribution. The cause of this is an inhomogeneous or asymmetrical doping profile along the well.

The asymmetry arises as a result of a scattering or reflection of the dopant particles at the edges of the resist masks that define the well regions during the implantation. This is because this implantation, in order to avoid the so-called channeling effect along a crystal direction lying perpendicular to the surface of the silicon substrate, is performed obliquely at an angle of 7 degrees, for example.

One solution consists in implementing a particularly wide trench isolation, e.g., STI: shallow trench isolation in the region of the well edges, so that effective backscattering into the substrate cannot occur there. However, this gives rise to a further source for asymmetries in the well doping profiles, because the trench isolation, during the further processing of the semiconductor substrate, leads to mechanical stresses in the adjoining substrate areas. These stresses may likewise locally influence the electrical properties in a disadvantageous manner. If the trench isolation lies closer to selected active transistors, this gives rise to a further source.

The problem has been avoided hitherto by designing the cell signal to be sufficiently strong corresponding to a generously dimensioned storage capacitor. Further endeavors amount to reducing the line capacitances. It is apparent, however, that these measures will soon no longer suffice in the context of increasing packing density, advancing structure miniaturization, rising leakage currents on account of tunnel effects, transistor leakage currents, so-called “'sub-Vt-leakage”, etc.

The document U.S. Pat. No. 6,445,216 B1 describes a sense amplifier having two input transistors of identical conductivity type, which are used to assess data signals D, D′. The influence of varying channel lengths between the transistors on the respective threshold voltage is reduced by virtue of the fact that a switching unit that generates the so-called “forward body bias” applies the same potential to the bulk terminals of the two transistors, for which purpose it is connected to the two terminals and the latter are interconnected.

### SUMMARY

In accordance with the present invention, a sense amplifier comprises at least two field effect transistors of identical conductivity type, each including a gate terminal, source terminal, drain terminal and bulk terminal. With regard to a first one of the field effect transistors, the gate terminal is connected to a signal line, the source terminal is connected to a terminal for feeding in a first supply voltage and the drain terminal is connected to a reference line. With regard to a second one of the field effect transistors, the gate terminal is connected to the reference line, the source terminal is connected to the terminal for feeding in the first supply voltage and the drain terminal is connected to the signal line. The first bulk terminal of the first field effect transistor is formed in a first well of a substrate and the second bulk terminal of the second field effect transistor is formed in a second well of the substrate, the second well being electrically insulated from the first well.

The two field effect transistors of identical conductivity type may be two n-FETs or two p-FETs which are assigned to the sense amplifier. Over and above the gate terminal, source terminal and drain terminal, they also have a bulk terminal to the substrate, or more precisely: to the respective well in or above which the n- or p-FETs are formed.

The two n-FETs or p-FETs are connected up in a negative-feedback manner. The gate terminals are connected oppositely either to the signal line or to the reference line. The drain terminals connect the transistor to the respective other one of the two lines. Therefore, they are connected via the line to the gate terminal of the respective other transistor of the pair. The source terminals are both connected to the same terminal for feeding in a supply potential. The terminal may, in particular, also have a means with which the supply potential of a potential source can be varied, can also be trimmed in accordance with one design of the invention, for instance by means of a further transistor.

The bulk terminals of the two n-FETs or p-FETs have the particular property of being electrically insulated from one another. That is to say the depletion regions of the transistors or the p-channels of the p-FETs or the n-channels of the n-FETs are respectively embedded in different n-wells or p-wells which are not in direct electrical contact with one another.

In other words: each transistor of an n-FET pair or of a p-FET pair comprises its own well, which is electrically isolated from that of the respective other transistor of the negative feedback pair. The isolation is preferably effected by an isolation trench, but may also be brought about by nonconductive, undoped substrate. An electrical connection between the two wells, which can be produced via at least one further switching element, is not precluded, however.

By virtue of the isolation of the wells and thus also of the bulk terminals, it is possible to match the geometry of the individual field effect transistors of a negative-feedback pair with regard to the well edges, in particular the distance between the depletion region and the well edge, or with regard to adjacent isolation regions which exert mechanical stresses. This gives rise to the advantage that the threshold voltages are no longer impaired by gradients of electrical parameters along the common well. The systematic offset is therefore cancelled. The threshold voltages of the two n- or p-FETs are thus close together.

On account of this, the risk of an erroneous read-out and amplification of a charge signal from a memory cell does not occur. To put it another way, the permissible strength of a cell signal can be reduced further, which has a positive effect on the dimensioning of a memory and also on the required power consumption.

One exemplary configuration of the sense amplifier provides for connecting the first well to a first means for feeding in a first well potential for setting a first threshold voltage of the first field effect transistor, and for connecting the second well to a second means for feeding in a second well potential—which is different from the first well potential—for setting a second threshold voltage of the second field effect transistor.

As a result, the threshold voltages of the two transistors can be coordinated with one another. Stochastic effects resulting from the formation of different wells can thus be compensated for individually for each of the wells by means of an adapted well potential.

The so-called body effect, which is also called the substrate bias effect, is utilized in this case. Accordingly, the threshold voltage of a field effect transistor correlates with the voltage present between gate and bulk terminal. This correlation can be calculated in order then to obtain the same threshold voltage for both n- or p-FETs depending on this. The values for the well potentials that can be read from the calculated relation for the desired threshold voltage are provided to the well potentials.

Supplying well potentials themselves also in turn comprise transistor providing a potential which is present from a further supply voltage and supplies the customary substrate bias voltage can be varied by up to 100 mV.

A method for providing well potentials in a sense amplifier according to the invention comprises: determining the threshold voltage without application of a well potential in each case of the first and of the second field effect transistor by measurement or simulation, in each case for the first and the second field effect transistor calculating a relation for a change—which is to be brought about by the body effect—in the threshold voltage of the first or second field effect transistor depending on a well potential to be applied, comparing the two relations for determining a first well potential for the first field effect transistor and a second well potential for the second field effect transistor, so that the threshold voltages of the first and second field effect transistors match in accordance with the relation, and separately setting the first circuit arrangement including transistors and the second circuit arrangement including transistors so that the first circuit arrangement can feed in the first well potential and the second circuit arrangement can feed in the second well potential.

The above and still further objects, features and advantages of the present invention will become apparent upon consideration of the following detailed description of specific embodiments thereof, particularly when taken in conjunction with the accompanying drawings wherein like reference numerals in the various figures are utilized to designate like components.

### BRIEF DESCRIPTION OF THE DRAWINGS

FIG. 1 shows a circuit arrangement with a sense amplifier for amplifying a signal read out from a memory cell;

FIG. 2 shows a diagram with two field effect transistors of a sense amplifier as in FIG. 1 in plan view in accordance with the prior art;

FIG. 3 shows a diagram as in FIG. 2 in accordance with the prior art, but in cross section along a line A-B;

FIG. 4 shows a diagram with two field effect transistors of a sense amplifier as in FIG. 1 in plan view, in accordance with an exemplary embodiment of the invention;

FIG. 5 shows a diagram as in FIG. 4 in accordance with an exemplary embodiment of the invention, but in cross section along a line A-B;

FIG. 6 shows three exemplary embodiments for generating separate well voltages for the field effect transistors shown in FIG. 1;

FIG. 7 shows an example of an interconnected connection of the wells for the field effect transistors shown in FIG. 1 in accordance with the prior art.

### DETAILED DESCRIPTION

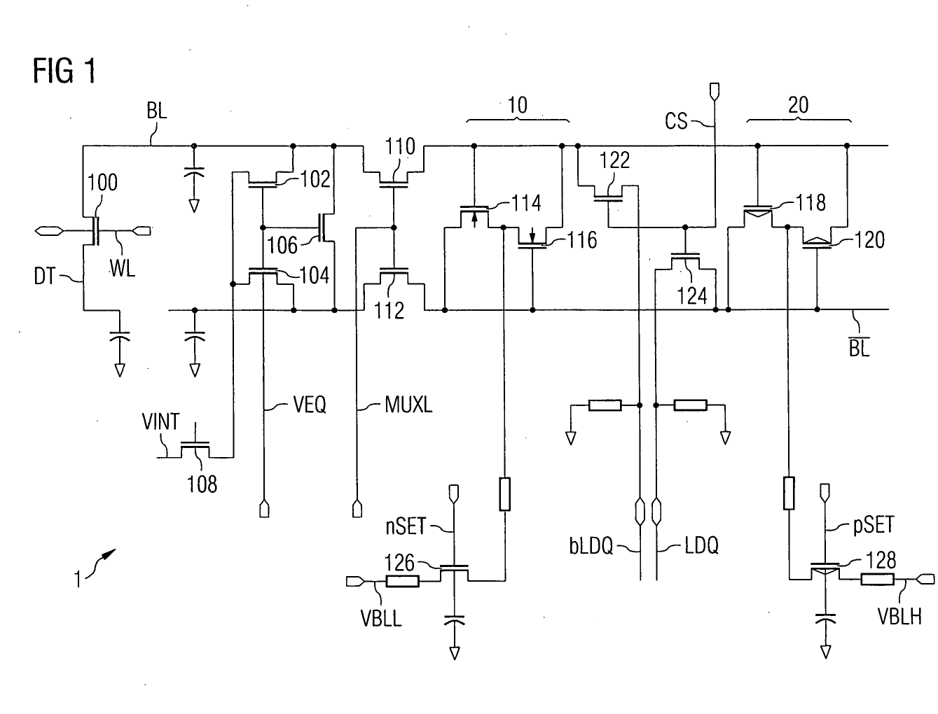

An example of a sense amplifier which is connected up for amplifying a charge signal read out from a memory cell is illustrated in FIG. 1. The arrangement will be explained on the basis of a read-out and amplification operation.

The selection transistor 100 is shown on the left-hand side of the illustration, which selection transistor, in controllable fashion via the word line WL, can enable a charge stored in the memory node DT. Before this operation is begun, however, first the bit line BL and the reference bit line \overline{BL} are brought to a common bias voltage potential (“precharge”). For this purpose, a voltage VINT of 900 mV is passed to the source inputs of the transistors 102, 104 via a transistor 108. Via the gate terminals of the transistors 102, 104, the latter are turned on by a voltage signal VEQ generated by a further source. Via the drain terminals, the bit line BL and reference bit line \overline{BL} are brought to exactly this voltage potential of 900 mV. The transistor 106, which is likewise turned on by means of the signal VEQ, has the effect that, in the case of a turn-on operation at a different speed, a potential equalization takes place between bit line BL and reference bit line \overline{BL}.

Independently of this, a further source generates a voltage signal MUXL, which can connect up the sense amplifier I both for the bit line BL and for the reference bit line \overline{BL}. If the signal is present at the gate terminals, the transistors 110 and 112 are turned on. The background for these enable transistors 110 and 112 is that, on the right-hand side of FIG. 1, a further memory cell of a different cell array can be connected to the same bit line. By means of the signals MUXL or MUXR (not shown in FIG. 1), either one cell or the other can be connected up to the same sense amplifier 1.

Afterward, the signal VEQ is ended and the transistor 108 can also be closed. The bit line BL and the reference bit line \overline{BL} now have the same potential, but are electrically isolated from one another. Then as described in the introduction through driving of the transistor 100, the charge is read out from the cell DT and is transferred onto the bit line BL. The resulting charge signal is limited according to strength and also with regard to the time duration. For example, a charge state of the memory cell DT “high” or “1” leads to a momentary increase in the voltage potential on the bit line by 160 mV to 1060 mV.

This potential is present at the input of the n-channel field effect transistor 114 (n-FET 114 for short). The n-FET 114 is one of the two transistors, connected in negative-feedback fashion, of a pair 10 having the same conductivity type which the sense amplifier 1 comprises. A voltage potential VBLL which can be trimmed by means of the signal nSET via the transistor 126 and initially has a value of 1800 mV is present at the source input of the n-FET 114.

The voltage potential is also present at the source input of the other n-FET 116 of the pair 10. The gate input thereof is connected to the bit line \overline{BL}, which still has a potential of 900 mV. The threshold voltage both of the n-FET 114 and of the n-FET 116 is 300 mV in each case in this example. The gate-source voltages of initially −740 mV (n-FET 114) and −900 mV (n-FET 116), respectively, result. Both transistors are closed.

The voltage potential VBLL is then continuously trimmed to 0 mV (“low”) by means of the transistor 126. At 760 mV for the potential VBLL, the n-FET 114 reaches the gate-source voltage of 300 mV, that is to say the threshold voltage, first. At the same point in time, the corresponding voltage at the n-FET 116 is still 140 mV. The n-FET 114 then opens, so that the reference bit line \overline{BL} is connected to the further decreasing potential VBLL. Its voltage potential is thus run down with it from 900 mV (bias voltage, precharge) to 0 mV (“low”).

The transistor 128 is controlled in a similar manner by means of a signal pSET in order to trim a potential VBLH from 0 mV to 1800 mV. In a manner opposite to the functioning of the n-FETs 114, 116, the p-FETs 118, 120 of the negative feedback pair 20 of transistors of the sense amplifier 1 are used in such a way that, in the present example, the voltage potential of the bit line BL is run up from 1060 mV (charge signal for “1”) to 1800 mV (“high”). The p-FET 120 turned on in this case. An initial difference between the voltage levels of 160 mV on account of the stored charge is thus raised to 1800 mV by the sense amplifier.

The previous example related to the ideal case of identical threshold voltages between the two n-FETS 114, 116 and/or the p-FETs 118, 120.

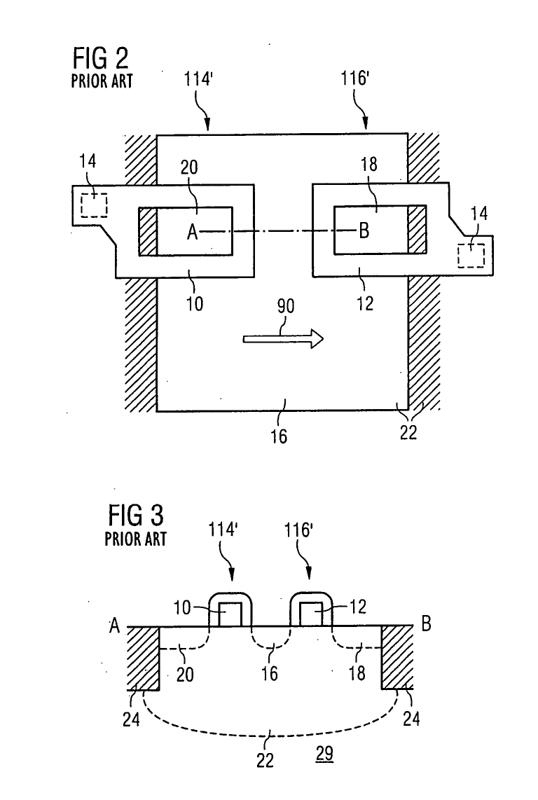

FIG. 2 (plan view) and FIG. 3 (cross section along line A-B) show an example of conventionally formed n-FETs 114′ and 116′. They comprise annular gate electrodes 10 and 12, respectively, an active source region 16, into which the potential VDLL can be fed (not shown in FIGS. 2, 3), and active drain regions 20, 18, which are connected to the bit line BL and, respectively, the reference bit line \overline{BL} (likewise not shown). The contacts 14 to the bit and reference bit lines are indicated for the gate electrodes 10, 12.

The transistors are formed above the same well 22. The resulting substrate or bulk terminal thus relates in principle to the same well potential.

As can be seen in FIG. 3, the active regions are delimited by a shallow trench isolation 24 (STI). The well 22 extends partly below the isolation 24 as well, so that its extent in area is somewhat larger than that of the active regions. Due to fabrication-dictated mechanical stresses, e.g., thermal processes, or on account of the effects of backscattering at resist edges during the oblique implantation, gradients 90 can occur in the electrical parameters of the well 22, which is illustrated by an arrow in FIG. 2.

In this example, in accordance with the prior art, this results in a difference in the threshold voltages of 100 mV, that is to say the n-FET 114 has a threshold voltage of 350 mV and the n-FET 116 has a threshold voltage of only 250 mV. On account of a memory cell error lying in the tolerance range, during the read-out of a charge signal only a voltage of 1000 mV is supplied on the bit line (potential difference of 100 mV instead of 160 mV on average).

In this possible case, it can happen that the n-FET 116 opens first even though a “high” signal is present. As a result, a potential of 0 mV is then present on the bit line BL and a potential of 1800 mV is present on the reference bit line \overline{BL}.

As additionally shown in FIG. 1, the two potentials are forwarded as signals bLDQ and LDQ to a controller via the further transistors 122, 124 on account of a select signal CS for this bit line, so-called column select signal.

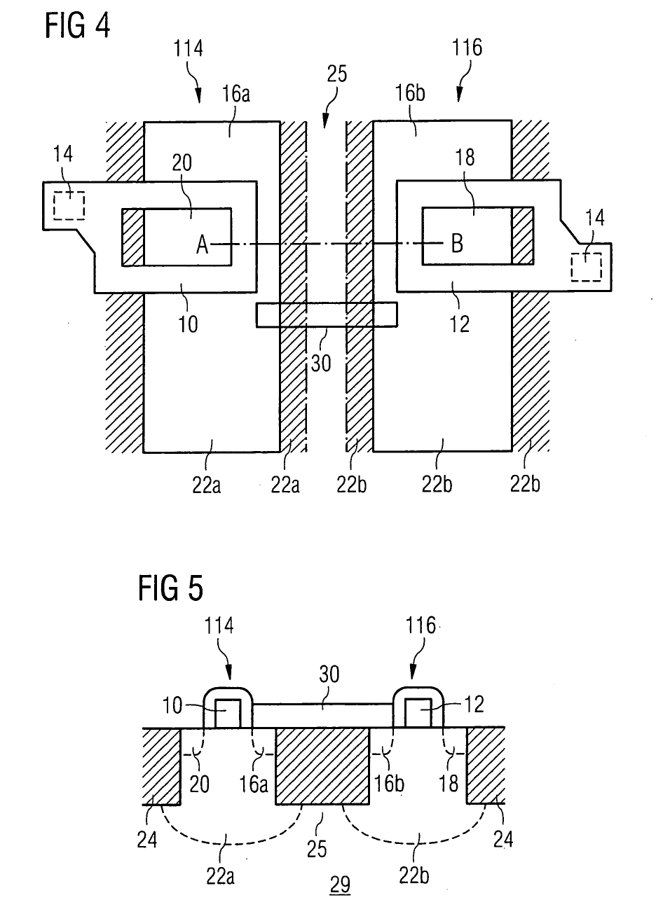

FIGS. 4 and 5 show an exemplary embodiment according to the invention in light of the arrangement shown in FIG. 1. The n-FETs 114, 116 are formed here via wells 22a, 22b that are electrically isolated from one another or insulated from one another by regions 30. The wells are at a distance 25 from one another in the substrate, so that interactions are precluded. The region 30 may involve the same trench isolation as in the case of the regions 24 (shallow trench isolation, STI). It is not ruled out for the wells 22a, 22b also to be isolated only by nonconductive substrate, that is to say undoped monocrystalline silicon, as is the case anyway below the isolation region 30. Accordingly, an isolation trench filled with SiO₂ is not a prerequisite for the isolation of the wells.

In the example, the source regions 16a and 16b are also isolated from one another. Since they have to be at the same potential VBLL in accordance with the arrangement according to FIG. 1, a conductive bridge 30 (surface strap, etc.) which electrically connects the two doping regions may be provided here. The connection 30 may also be provided in the planar surface or in some other way. Separate connections of the source regions 16a, 16b by means of contacts to interconnects of a superordinate wiring plane to the same voltage, trimming or supply potential VBLL are also conceivable. The invention is not restricted to these individual embodiments.

For the contacts 14 of the gate electrodes and the drain regions 16, 18, in this exemplary embodiment there are no structural differences with respect to the prior art in accordance with FIG. 2 or 3.

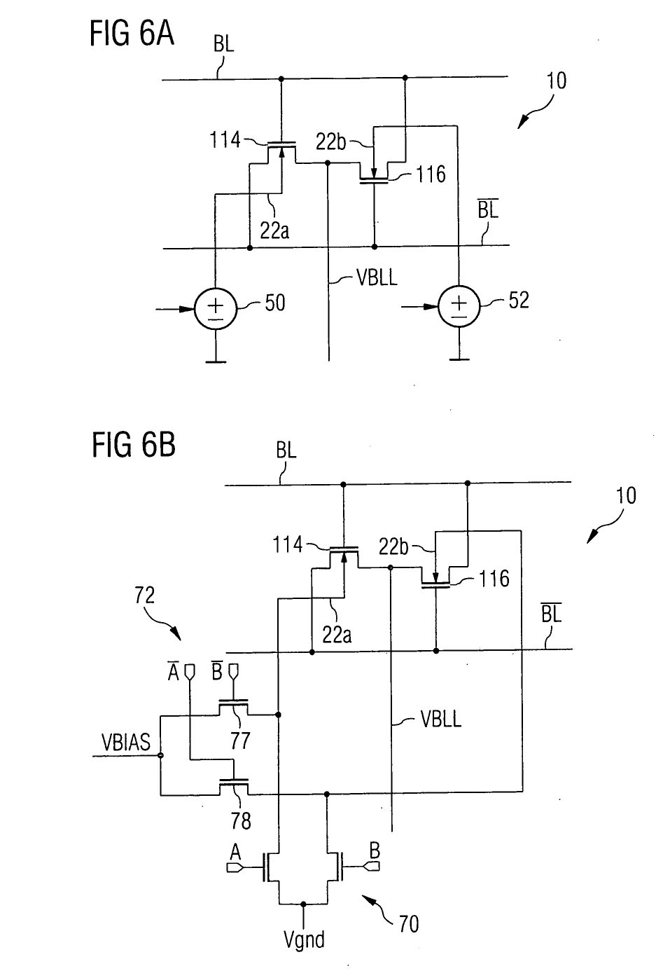

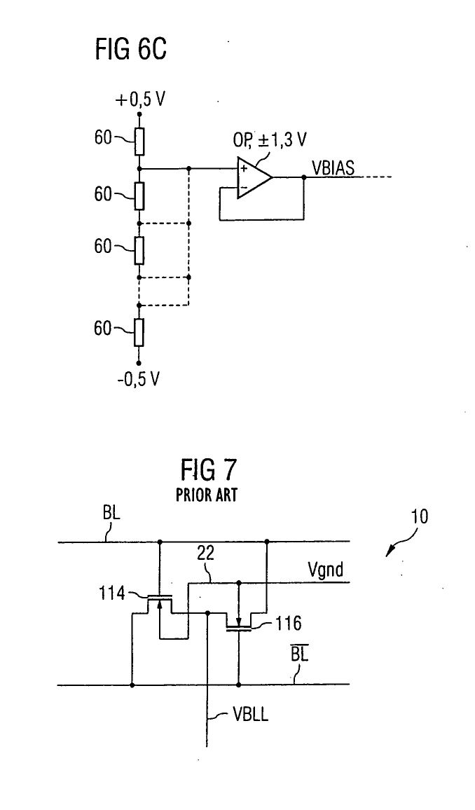

An example of the generation of separate well voltages for the n-FETs 114, 116 shown in FIG. 1 can be seen in the circuit diagram of FIG. 6a. In this case, the well terminals 22a, 22b of the two n-FETs 114, 116 are connected to respectively different means 50, 52 which supply different voltage potentials.

FIG. 6b shows a detailed example of the different potential sources. Via signals A, B, a basic potential Vgnd (e.g. 0 mV) is respectively switched to the well terminals 22a, 22b in a controllable manner. The potentials present can now be modified, however, specifically in that transistors which are controllable by sources of signals \overline{A}, \overline{B} can switch in a correction voltage potential VBIAS, “bias voltage”, for a respective one of the well terminals. A direct electrical connection between the potentials present at the different wells 22a, 22b no longer exists in this case.

In this exemplary embodiment, the signals \overline{A}, \overline{B} and also the associated two transistors constitute a source 72, by which the basic potential Vgnd present at the wells can be varied. However, the invention is not restricted to this specific embodiment for the source 72. Rather, other sources 72 are also conceivable which can be used to generate different bias voltages VBIAS for the respective wells.

FIG. 6c shows an optionally usable exemplary embodiment of a circuit arrangement by means of which the bias voltage VBIAS can be generated. Via voltage divider resistors 60, which make it possible to tap off potentials between +0.5 V and −0.5 V, a predetermined potential is applied to an operational amplifier OP. The operational amplifier OP has an operating voltage of between, e.g., −1.3 volts and +1.3 volts.

FIG. 7 shows an embodiment in accordance with the prior art. In this case, the two wells 22a, 22b are not only connected to one another but are also connected to a common basic potential (substrate voltage) Vgnd.

While the invention has been described in detail and with reference to specific embodiments thereof, it will be apparent to one skilled in the art that various changes and modifications can be made therein without departing from the spirit and scope thereof. For example, the invention is not restricted to the feature combinations shown in the exemplary embodiments. Rather, it also encompasses those alternative features which the person skilled in the art, using his expert knowledge, would routinely interchange with the combinations presented here in order to achieve the same aim. In particular, the invention is not restricted to the area of application in memory components. Accordingly, it is intended that the present invention covers the modifications and variations of this invention provided they come within the scope of the appended claims and their equivalents.

### LIST OF REFERENCE SYMBOLS

1 Sense amplifier
10 Pair of n-FETs coupled back-to-back
20 Pair of p-FETs coupled back-to-back
14 Contacts
16, 16a, 16b Source regions
18, 20 Drain regions
22, 22a, 22b Wells
24, 30 Isolation regions
25 Distance between the wells
30 Conductive region
70, 72 Circuit arrangement for adapting the well potential
77, 78 Transistors of the arrangement for feeding in the bias voltage potential
100-128 Transistors, including:
100 Selection transistor in memory cell
114, 116 n-FETs
118, 120 P-FETs
DT Memory node
BL Bit line
\overline{BL} Reference bit line
VINT Bias voltage for bit lines
VEQ Signal for bias voltage
MUXL Select signal for cell array of the memory cell
VBIAS Bias voltage potential, adaptation potential
VBLL Supply voltage “low”
VBLH Supply voltage “high”
Vgnd Basic potential
nSET Signal for trimming VBLL
pSET Signal for trimming VBLH
CS Select signal for bit line
BLDQ, LDQ Read-out signals to the controller

What is claimed is:

1. A sense amplifier, comprising:
a substrate; and
a plurality of field effect transistors including a first transistor and a second transistor, wherein the first and second transistors are of identical conductivity type and each transistor comprises a gate terminal, a source terminal, a drain terminal and a bulk terminal;
wherein:
the gate terminal of the first transistor is connected to a signal line, the source terminal of the first transistor is connected to a first supply voltage, the drain terminal of the first transitor is connected to a reference line and the bulk terminal of the first transistor is formed in a first well of the substrate;
the gate terminal of the second transistor is connected to the reference line, the source terminal of the second transistor is connected to the first supply voltage, the drain terminal of the second transistor is connected to the signal line and the bulk terminal of the second transistor is formed in a second well of the substrate; and
the second well is electrically insulated from the first well.

2. The sense amplifier according to claim 1, wherein
the first well is connected to a first circuit arrangement comprising a plurality of transistors, wherein the first circuit arrangement is configured to set a first threshold voltage providing a first well potential of the first transistor and
the second well is connected to a second circuit arrangement comprising a plurality of transistors, wherein the second circuit arrangement is configured to set a second threshold voltage providing a second well potential of the second transistor, wherein the second well potential is different from the first well potential.

3. The sense amplifier according to claim 2, wherein the first and second circuit arrangements that provide the first and second well potentials are further configured to set the first and second well voltages such that the difference between the first and second well potentials compensates for a variance in conductivity of the first and second wells and imposes uniformity of threshold voltages on the first and second transistors.

4. The sense amplifier according to claim 1, wherein the signal line connects to a bit line of a memory cell that stores electrical charges.

5. The sense amplifier according to claim 4, wherein the reference line is a reference bit line.

6. The sense amplifier according to claim 1, wherein the plurality of field effect transistors further includes a third transistor and a fourth transistor, and the third and fourth transistors are of opposite conductivity type to the conductivity type of the first and second transistors.

7. The sense amplifier according to claim 2, wherein the first and second circuit arrangements together further comprise:
a third circuit arrangement to feed in a well basic potential; and
a fourth circuit arrangement to adapt the well basic potential to the well potential of the first well connected to the first circuit arrangement or to the second well connected to the second circuit arrangement.

8. The sense amplifier according to claim 7, wherein the difference between the well basic potential and the first well potential or the second well potential is less than 100 millivolts.

9. The sense amplifier according to claim 7, wherein the fourth circuit arrangement comprises a plurality of transistors with source terminals that are connected to a bias voltage potential.

10. The sense amplifier according to claim 9, wherein each of the transistors of the fourth circuit arrangement includes a drain terminal that is connected to the corresponding bulk terminal of the first and second transistors so as to facilitate independent control of the well potentials of the first and second wells by independent control of each transistor of the fourth circuit arrangement.

11. A sense amplifier, comprising:
a substrate;
a plurality of field effect transistors including a first transistor and a second transistor, wherein the first and second transistors are of identical conductivity type and each transistor comprises a gate terminal, a source terminal, a drain terminal and a bulk terminal, the gate terminal of the first transistor being connected to a signal line;
wherein:
the source terminal of the first transistor is connected to a first supply voltage, the drain terminal of the first transistor is connected to a reference line and the bulk terminal of the first transistor is connected to a first circuit arrangement, the first circuit arrangement comprising transistors and being configured to set a first threshold voltage that provides a first well potential of the first transistor;
the gate terminal of the second transistor is connected to the reference line, the source terminal of the second transistor is connected to the first supply voltage, the drain terminal of the second transistor is connected to the signal line and the bulk terminal of the second transistor is connected to a second circuit arrangement, the second circuit arrangement comprising transistors and being configured to set a second threshold voltage that provides a second well potential of the second field effect transistor; and
the first and second well potentials are different.

12. The sense amplifier according to claim 11, wherein the first and second circuit arrangements that provide the first and second well potentials are further configured to set the first and second well voltages such that the difference between the first and second well potentials compensates for a variance in conductivity of the first and second wells and imposes uniformity of threshold voltages on the first and second transistors.

13. The sense amplifier according to claim 11, wherein the signal line connects to a bit line of a memory cell that stores electrical charges.

14. The sense amplifier according to claim 11, wherein the reference line is a reference bit line.

15. The sense amplifier according to claim 11, wherein the plurality of field effect transistors further includes a third transistor and a fourth transistor, and the third and fourth transistors are of opposite conductivity type to the conductivity type of the first and second transistors.

16. The sense amplifier according to claim 11, wherein the first and second circuit arrangements together further comprise:
a third circuit arrangement to feed in a well basic potential; and
a fourth circuit arrangement to adapt the well basic potential to the well potential of the first well connected to the first circuit arrangement or to the second well connected to the second circuit arrangement.

17. The sense amplifier according to claim 16, wherein the difference between the well basic potential and the first or the second well potential is less than 100 millivolts.

18. The sense amplifier according to claim 17, wherein the fourth circuit arrangement comprises a plurality of transistors with source terminals that are connected to a bias voltage potential.

19. A method for setting well potentials in a sense amplifier, the sense amplifier comprising a substrate, and a plurality of field effect transistors including a first transistor and a second transistor, wherein the first and second transistors are of identical conductivity type and each transistor comprises a gate terminal, a source terminal, a drain terminal and a bulk terminal, the gate terminal of the first transistor being connected to a signal line, the source terminal of the first transistor being connected to a first supply voltage, the drain terminal of the first transistor being connected to a reference line and the bulk terminal of the first transistor being connected to a first circuit arrangement, the first circuit arrangement comprising transistors and being configured to set a first threshold voltage that provides a first well potential of the first transistor, the gate terminal of the second transistor being connected to the reference line, the source terminal of the second transistor being connected to the first supply voltage, the drain terminal of the second transistor being connected to the signal line and the bulk terminal of the second transistor being connected to a second circuit arrangement, the second circuit arrangement comprising transistors and being configured to set a second threshold voltage that provides a second well potential of the second field effect transistor, and the second well being electrically insulated from the first well, the method comprising:
(a) determining the threshold voltage without application of a well potential in each of the first and second transistors by measurement or simulation;
(b) for each of the first and second transistors, calculating a relation for a change that is induced by a body effect in the threshold voltage of the first or second field effect transistor depending on a well potential to be applied;
(c) comparing the two calculated relations so as to determine a first well potential for the first transistor and a second well potential for the second transistor, such that the threshold voltages of the first and second transistors match according to the calculated relations for each of the first and second transistors; and
(d) separately setting the first circuit arrangement and the second circuit arrangement such that the first circuit arrangement provides the first well potential, and the second circuit arrangement provides the second well potential.
